(19) United States
(12) Patent Application Publication
(10) Pub. No.: US 2008/0150122 A1
(43) Pub. Date: Jun. 26, 2008

(54) Routing density through asymmetric array of vias

(76) Inventors: Cliff Lee, Portland, OR (US); David Browning, Beaverton, OR (US); Brian Kelly, Hillsboro, OR (US)

Correspondence Address: CAVEN & AGHEVLI;c/o INTELLEVATE, LLC, P.O. BOX 52050, MINNEAPOLIS, MN, 55402, US

(21) Appl. No.: 11/645,820

(22) Filed: Dec. 26, 2006

(51) Int. Cl. H01L 23/48; H01L 21/4763

(52) U.S. Cl. 257/698; 438/618; 257/E23.01; 257/E21.495

(57) ABSTRACT

Methods and apparatus to improve routing density through asymmetric array of vias are described. In one embodiment, a plurality of vias may be asymmetrically distributed relative to the distribution of a plurality of pads. Other embodiments are also described.

### BACKGROUND

The present disclosure generally relates to the field of electronics. More particularly, an embodiment of the invention generally relates to a package on package design that may improve functionality and/or efficiency.

A computer system generally includes various components that may be connected to a motherboard. Some of the components may be permanently attached to the motherboard. Other components may be mounted on a socket and the socket may be in turn permanently attached to the motherboard. Generally, a uniform field of vias in the motherboard may be used to route various signals to and from a component mounted on a socket. Differential signaling utilizes a pair of signals for communication. A uniform field of vias, however, may restrict the number of signals that may be routed through a motherboard in accordance with differential signaling.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIGS. 1-4 illustrate various views of components of devices in accordance with some embodiments of the invention.

FIG. 5 illustrates a block diagram of a method according to an embodiment.

FIG. 6 illustrates a block diagram of a computing system, which may be utilized to implement various embodiments discussed herein.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

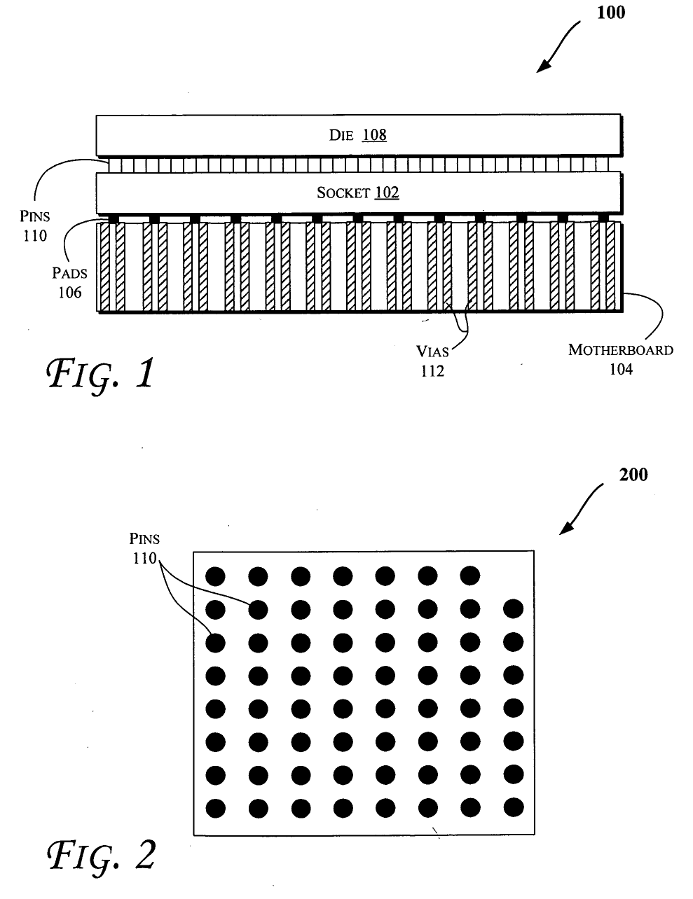

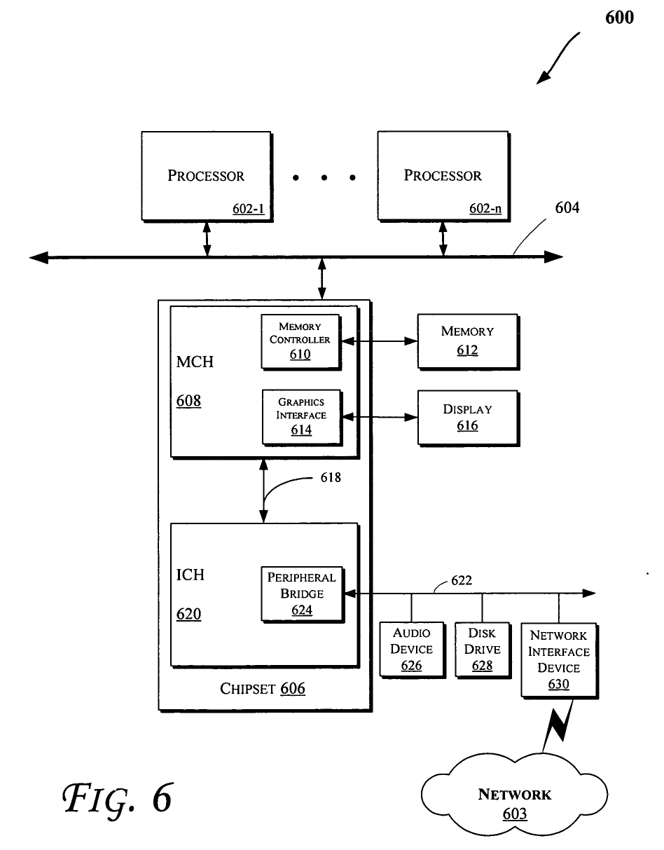

Some embodiments discussed herein (e.g., with reference to FIGS. 1-6) may improve routing density through asymmetric array of vias. More particularly, FIG. 1 illustrates components of a device 100 in accordance with an embodiment of the invention. The device 100 may include a socket 102, a motherboard 104, and an integrated circuit (IC) die 108. As shown in FIG. 1, the motherboard 104 may be coupled to the socket 102 through pads 106 which may be soldered to provide an electrical connection between the socket 102 and motherboard 104. The socket 102 may receive pins 110 from the die 108 to establish an electrical connection between the die 108 and motherboard 104. Further, the motherboard 104 may include vias 112, e.g., to enable routing of signals between various components of a computing system such as the system discussed with reference to FIG. 6. Also, the die 108 may include any type of logic such as one or more processor cores, memory units, chipsets, or other components (e.g., such as the components discussed with reference to FIG. 6). In an embodiment, vias 112 may be constructed with any electrically conductive material such as aluminum, copper, silver, gold, combinations thereof, or other electrically conductive material.

FIG. 2 illustrates an arrangement of pins in a device 200 in accordance with an embodiment. The device 200 may include the pins 110. Hence, FIG. 2 illustrates a top (or bottom) view of the pins 110 of die 108 of FIG. 1. As illustrated, the pins 110 may be distributed uniformly in an embodiment. Also, in an embodiment, the socket 102 of FIG. 1 may include corresponding holes to receive the pins 110 of FIG. 2. Alternatively, the pins 110 may be provided on the socket 102 and the corresponding holes may be provided on the die 108. Furthermore, a combination of pins and corresponding holes may be provided on each of the die 108 and socket 102.

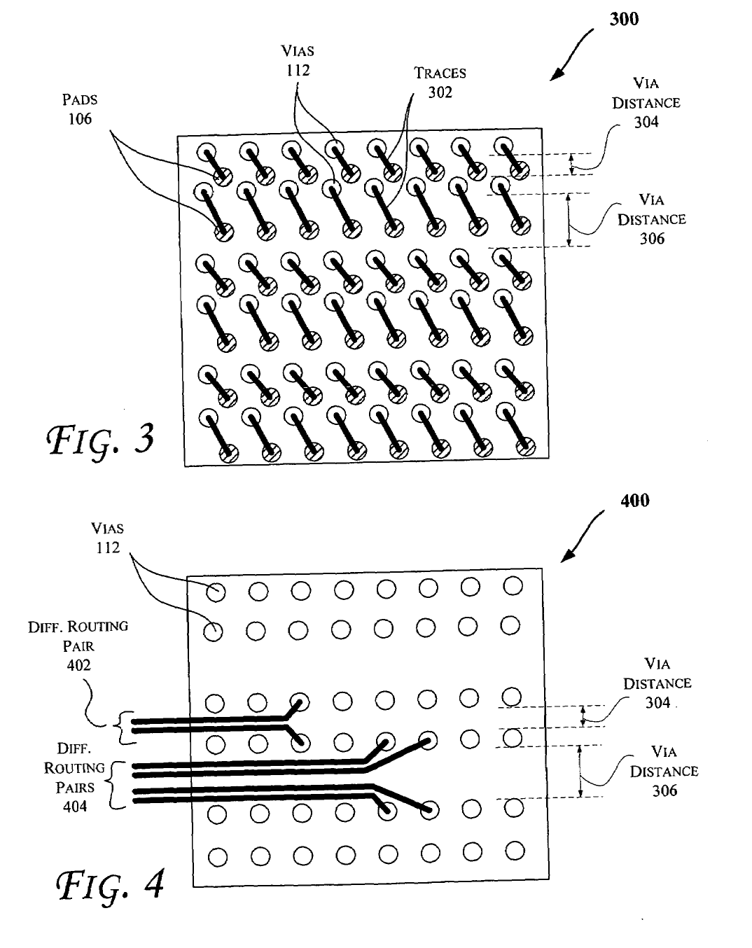

FIG. 3 illustrates an arrangement of vias, pads, and wire traces in a device 300 in accordance with an embodiment. The arrangement shown in FIG. 3 may be provided within a portion of the motherboard 104 of FIG. 1 (e.g., on the top side of the motherboard 104 that faces the socket 102 in FIG. 1). The pads 106 are illustrated in FIG. 3 as shaded circles while the vias 112 are illustrated without shades. The pads 106 may have the same distribution as the pins 110 of FIGS. 1-2, e.g., a symmetric or uniform distribution such as shown with reference to the pins 110 in FIG. 2. In an embodiment, each of the pads 106 may be coupled to a corresponding one of the pins 110 through the socket 102. Also, as shown in FIG. 3, each of the pads 106 may be coupled to a corresponding one of the vias 112 through wire traces 302. Further, the spacing between vias may be asymmetric. For example, distance 304 may be shorter than distance 306. In an embodiment, the distance 304 may be about 12 mils and distance 306 may be about 28 mils.

FIG. 4 illustrates an arrangement of vias and signal routes in a device 400 in accordance with an embodiment. The arrangement shown in FIG. 4 may be provided within a portion of the motherboard 104 of FIG. 1 (e.g., on the bottom side of the motherboard 104 that faces away from the socket 102 in FIG. 1 or within an inner layer of the mother board 104 of FIG. 1). In one embodiment, the signal routes shown in FIG. 4 (e.g., routes 402 and/or 404) may be differential signal routes. Hence a pair of signals may be used differentially to communicate a signal. In an embodiment, sets of vias 112 (e.g., rows shown in FIG. 4) may be spaced such that every other set of vias is spaced further away from the next set of vias relative to the previous set of vias. Such an embodiment may provide an improved density of routes in the motherboard 104 of FIG. 1. For example, while the differential routing pair 402 is provided within the distance 304, the differential routing pairs 404 may be provided within the distance 306. In an embodiment, printed circuit board (PCB) differential trace routing density (e.g., within the motherboard 104) may be increased for various types of sockets (e.g., the socket 102) such as a micro pin grid array (μPGA) socket, a land grid array (LGA) socket, etc., by using an asymmetric array of vias 112 (such as illustrated in FIGS. 3 and 4).

In some embodiments, the differential routing signal density may be increased by providing an asymmetric array of vias 112 in the breakout region of signals. In accordance with an embodiment, an example will now be discussed with reference to physical parameters to indicate potential results and impact. Mobile processor sockets (e.g., μPGA 479) may utilize a uniform grid of pins with a pin pitch of 50 mils (see, e.g., FIG. 2). Some breakout routing of each of these pins to a corresponding via yields a uniform via field of 50 mils pitch. The mobile high volume manufacturing (HVM) via size may utilize a 30 mil antipad which may act as a routing keep-out zone. The resulting routing area between vias may be about 20 mils. High speed routing for mobile designs may be done on internal routing layers (strip-line layers) of the motherboard 104. The mobile HVM trace width on strip-line layers may be about 4 mils with a trace-to-trace space of 4 mils. So, inside of the 20 mil routing channel between vias, three signals may be routed (e.g., 3×4 mil traces+2×4 mil spaces=20 mils). This routing density may work well for some interfaces that do not utilize differential signaling. However, some interfaces which may utilize differential signal traces may be capable of fitting a single pair (2 traces) between the vias with the above detailed sizes. Thus, a uniform (or symmetrical) via field may provide for one differential pair per routing channel. Some embodiments however overcome this restriction by providing sufficient space for a third signal trace between the vias (see, e.g., FIG. 4). In one embodiment, one row of vias may be moved up by 4 mils and the adjacent row of vias may be moved down by 4 mils. On the outer layer, these vias may be still far enough away from the pins to meet HVM requirements. On the inner routing layers, one of the routing channels may be reduced from 20 mils to 12 mils (4 mil reduction on both sides such as the distance 304) which may be still wide enough to allow for one differential pair (e.g., pair 402) to fit within the routing channel (e.g., 2×4 mil traces+1×4 mil space=12 mils). The other routing channel may be increased from 20 mils to 28 mils (4 mil increase on both sides such as the distance 306) which may be wide enough to allow for two differential pairs (e.g., pairs 404) to fit within the routing channel (4×4 mil traces+3×4 mil space=28 mils). Hence, some embodiments of the invention may allow for three differential routing pairs for every two rows (and/or columns depending on the implementation) of vias which may be in turn a 50% increase in differential routing density (see, e.g., FIG. 4).

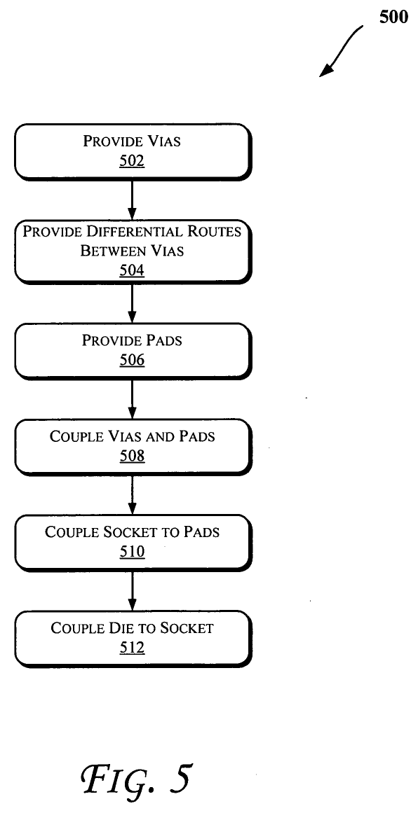

FIG. 5 illustrates a block diagram of an embodiment of a method 500 to improve routing density. In an embodiment, various components discussed with reference to FIGS. 1-4 and 6 may be utilized to perform one or more of the operations discussed with reference to FIG. 5. For example, the method 500 may be used to provide the devices 100 of FIG. 1.

Referring to FIGS. 1-5, at an operation 502, vias may be provide (e.g., such as the vias 112). At an operation 504, differential routes (e.g., routing pairs 402 and/or 404) may be provided between the vias (e.g., the vias 112). At an operation 506, pads may be provided (such as the pads 106). The vias and pads may be coupled at an operation 508 (e.g., through the traces 302). At an operation 510, a socket (e.g., socket 102) may be coupled to the pads (e.g., pads 106). A die (e.g., die 108) may be coupled to the socket (e.g., socket 102) at an operation 512.

FIG. 6 illustrates a block diagram of a computing system 600 in accordance with an embodiment of the invention. The computing system 600 may include one or more central processing unit(s) (CPUs) 602 or processors that communicate via an interconnection network (or bus) 604. The processors 602 may include a general purpose processor, a network processor (that processes data communicated over a computer network 603), or other types of a processor (including a reduced instruction set computer (RISC) processor or a complex instruction set computer (CISC)). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors. Moreover, the operations discussed with reference to FIGS. 1-5 may be performed by one or more components of the system 600.

A chipset 606 may also communicate with the interconnection network 604. The chipset 606 may include a memory control hub (MCH) 608. The MCH 608 may include a memory controller 610 that communicates with a memory 612. The memory 612 may store data, including sequences of instructions that are executed by the CPU 602, or any other device included in the computing system 600. In one embodiment of the invention, the memory 612 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 604, such as multiple CPUs and/or multiple system memories.

The MCH 608 may also include a graphics interface 614 that communicates with a display 616. In one embodiment of the invention, the graphics interface 614 may communicate with the display 616 via an accelerated graphics port (AGP). In an embodiment of the invention, the display 616 may be a flat panel display that communicates with the graphics interface 614 through, for example, a signal converter that translates a digital representation of an image stored in a storage device such as video memory or system memory into display signals that are interpreted and displayed by the display 616. The display signals produced by the interface 614 may pass through various control devices before being interpreted by and subsequently displayed on the display 616.

A hub interface 618 may allow the MCH 608 and an input/output control hub (ICH) 620 to communicate. The ICH 620 may provide an interface to I/O devices that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the CPU 602 and peripheral devices. Other types of topologies may be utilized. Also, multiple buses may communicate with the ICH 620, e.g., through multiple bridges or controllers. Moreover, other peripherals in communication with the ICH 620 may include, in various embodiments of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603). Other devices may communicate via the bus 622. Also, various components (such as the network interface device 630) may communicate with the MCH 608 in some embodiments of the invention. In addition, the processor 602 and the MCH 608 may be combined to form a single chip. Furthermore, the graphics accelerator 616 may be included within the MCH 608 in other embodiments of the invention.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions). In an embodiment, components of the system 600 may be arranged in a point-to-point (PtP) configuration. For example, processors, memory, and/or input/output devices may be interconnected by a number of point-to-point interfaces.

In various embodiments of the invention, the operations discussed herein, e.g., with reference to FIGS. 1-6, may be implemented as hardware (e.g., logic circuitry), software, firmware, or combinations thereof, which may be provided as a computer program product, e.g., including a machine-readable or computer-readable medium having stored thereon instructions (or software procedures) used to program a computer to perform a process discussed herein. The machine-readable medium may include a storage device such as those discussed with respect to FIGS. 1-6.

Additionally, such computer-readable media may be downloaded as a computer program product, wherein the program may be transferred from a remote computer (e.g., a server) to a requesting computer (e.g., a client) by way of data signals embodied in a carrier wave or other propagation medium via a communication link (e.g., a bus, a modem, or a network connection). Accordingly, herein, a carrier wave shall be regarded as comprising a machine-readable medium.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. An apparatus comprising:
a plurality of vias that are distributed asymmetrically in a motherboard relative to a distribution of a plurality of pads, wherein the plurality of vias are coupled to the plurality of pads through a plurality of wire traces.

2. The apparatus of claim 1, further comprising a socket to receive a plurality of pins from an integrated circuit die and to couple the plurality of pins to the plurality of pads.

3. The apparatus of claim 1, wherein each of the plurality of wire traces is to couple one via from the plurality of vias with a corresponding pad from the plurality of pads.

4. The apparatus of claim 1, further comprising a first pair of differential signal routes located between a first set of the plurality of the vias and a second set of the plurality of vias.

5. The apparatus of claim 4, further comprising a second pair of differential signal routes located between the second set of the plurality of the vias and a third set of the plurality of vias.

6. The apparatus of claim 5, further comprising a third pair of differential signal routes located between the second set of the plurality of the vias and the third set of the plurality of vias.

7. The apparatus of claim 5, wherein the first set of the plurality of the vias and the second set of the plurality of vias are about 12 mils apart.

8. The apparatus of claim 5, wherein the second set of the plurality of the vias and the third set of the plurality of vias are about 28 mils apart.

9. The apparatus of claim 1, further comprising a socket to receive a plurality of pins from an integrated circuit die and to couple the plurality of pins to the plurality of pads, wherein the integrated circuit die comprises one or more processor cores.

10. A method comprising:
distributing a plurality of vias asymmetrically in a motherboard relative to a distribution of a plurality of pads,
wherein the plurality of vias are coupled to the plurality of pads through a plurality of wire traces.

11. The method of claim 10, further comprising coupling a socket to receive a plurality of pins from an integrated circuit die.

12. The method of claim 11, further comprising coupling the plurality of pins to the plurality of pads.

13. The method of claim 10, further comprising providing a first pair of differential signal routes located between a first set of the plurality of the vias and a second set of the plurality of vias.

14. The method of claim 13, further comprising providing a second pair of differential signal routes located between the second set of the plurality of the vias and a third set of the plurality of vias.

15. The method of claim 14, further comprising providing a third pair of differential signal routes located between the second set of the plurality of the vias and the third set of the plurality of vias.
